(19) United States
(12) Patent Application Publication
(10) Pub. No.: US 2023/0159381 A1
(43) Pub. Date: May 25, 2023

(54) METHOD OF MAKING A COATED GLASS ARTICLE

(71) Applicant: PILKINGTON GROUP LIMITED, LATHOM (GB)

(72) Inventors: JUN NI, MAUMEE, OH (US); SRIKANTH VARANASI, OTTAWA HILLS, OH (US)

(73) Assignee: PILKINGTON GROUP LIMITED, LATHOM (GB)

(21) Appl. No.: 17/919,789

(22) PCT Filed: Apr. 22, 2021
(86) PCT No.: PCT/GB2021/050962

§ 371 Date: Oct. 19, 2022

Related U.S. Application Data
(60) Provisional application No. 63/014,269, filed on Apr. 23, 2020.

(51) Int. Cl. C03C 17/245; C03C 17/34

(52) U.S. Cl. CPC C03C 17/245; C03C 17/3417; C03C 2218/1525; C03C 2217/23; C03C 2217/283

(57) ABSTRACT

The invention provides a method of making a coated glass article in which a gaseous mixture is formed including an aluminum-containing compound, a boron-containing compound, and an inert gas. This gaseous mixture is delivered to a location above a major surface of a glass substrate to deposit a coating comprising aluminum, boron, and oxygen over the major surface of the glass substrate.

### BACKGROUND OF THE INVENTION

The invention relates in general to a method of making a coated glass article. More particularly, the invention relates to a method of making a coated glass article that includes depositing a coating comprising aluminum and oxygen over a glass substrate.

Processes for depositing coatings on glass are known. However, the known processes are limited by the efficiency of the deposition process. Therefore, it would be desirable to provide an improved method for making a coated glass article.

### SUMMARY OF THE INVENTION

The invention provides a method of making a coated glass article in which a gaseous mixture is formed including an aluminum-containing compound, a boron-containing compound, and an inert gas. This gaseous mixture is delivered to a location above a major surface of a glass substrate to deposit a coating comprising aluminum, boron, and oxygen over the major surface of the glass substrate.

### BRIEF DESCRIPTION OF THE DRAWING

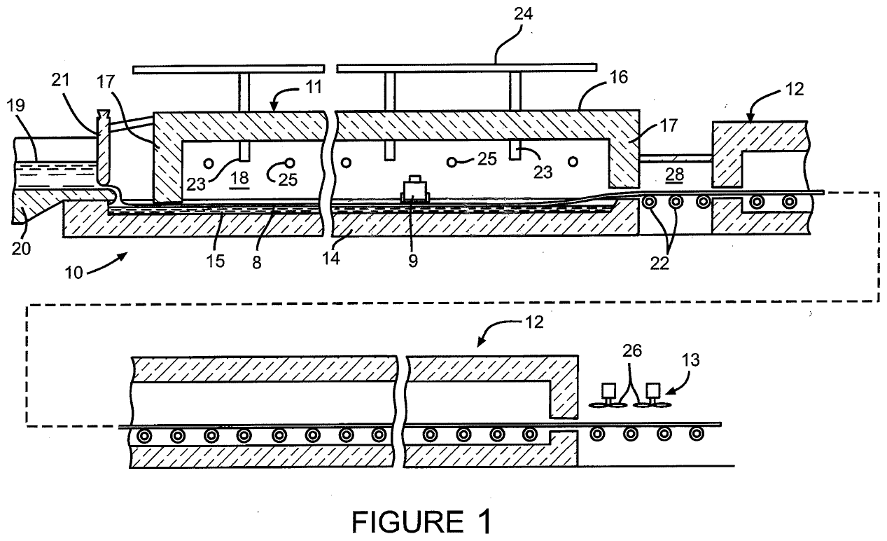

The above, as well as other advantages of the process will become readily apparent to those skilled in the art from the following detailed description when considered in the light of the accompanying drawing in which the FIG. 1 depicts a schematic view, in vertical section, of an installation for practicing the float glass manufacturing process in accordance with certain embodiments of the invention.

### DETAILED DESCRIPTION OF THE INVENTION

It is to be understood that the invention may assume various alternative orientations and step sequences, except where expressly specified to the contrary. It is also to be understood that the specific articles, apparatuses, and methods described in the following specification are simply exemplary embodiments of the inventive concepts. Hence, specific dimensions, directions, or other physical characteristics relating to the embodiments disclosed are not to be considered as limiting, unless expressly stated otherwise. Also, although they may not be, like elements in the various embodiments described within this section of the application may be commonly referred to with like reference numerals.

In an embodiment, a method for making a coated glass article is provided. The coated glass article may be utilized in an enclosure, a residential glazing, or a commercial glazing. Additionally, the coated glass article may have automotive, architectural, aerospace, industrial, locomotive, naval, electronic, and photovoltaic applications.

The method comprises providing a glass substrate. The glass substrate comprises a major surface over which a coating is formed. In some embodiments, the glass substrate is not limited to a particular thickness. However, in certain embodiments, the glass substrate may have a thickness of 20.0 millimeters (mm) or less.

The glass substrate may be of any of the conventional glass compositions known in the art. Preferably, the glass substrate is a soda-lime-silica glass. When the glass substrate is a soda-lime-silica glass, the glass substrate may comprise 68-74 weight % SiO₂, 0-3 weight % Al₂O₃, 0-6 weight % MgO, 5-14 weight % CaO, 10-16 weight % Na₂O, 0-2 weight % SO₃, 0.005-4.0 weight % Fe₂O₃ (total iron), and 0-5 weight % K₂O. As used herein, the phrase “total iron” refers to the total weight of iron oxide (FeO+Fe₂O₃) contained in the glass calculated as Fe₂O₃. The glass may also contain other additives, for example, refining agents, which would normally be present in an amount of up to 2%. In this embodiment, the glass substrate may be provided as a portion of a float glass ribbon. When the glass substrate is formed as a portion of a float glass ribbon, the glass substrate may be clear float glass. In some of these embodiments, clear float glass may mean a glass having a composition as defined in a related standard such as BS EN 572-1:2012+A1:2016 and BS EN 572-2:2012. However, the glass substrate may be of another composition such as, for example, a borosilicate or aluminosilicate composition.

The color of the glass substrate can vary between embodiments of the coated glass article. In some embodiments, the glass substrate may be clear. In these embodiments, the glass substrate may exhibit a total visible light transmittance of 88% or more when measured at a reference thickness of 2.1 mm in the CIELAB color scale system (Illuminant C, 10 degree observer). In one such embodiment, the glass substrate has a low iron content, which allows for the high visible light transmittance. For example, the glass substrate may comprise 0.20 weight % Fe₂O₃ (total iron) or less. More preferably, in this embodiment, the glass substrate comprises 0.1 weight % Fe₂O₃ (total iron) or less, and, even more preferably, a 0.02 weight % Fe₂O₃ (total iron) or less. In still other embodiments, the glass substrate may be tinted or colored.

The method may be carried out in conjunction with the manufacture of the glass substrate. In an embodiment, the glass substrate may be formed utilizing the well-known float glass manufacturing process. An example of a float glass manufacturing process is illustrated in the FIG. 1. In this embodiment, the glass substrate may also be referred to as a glass ribbon. However, it should be appreciated that the method can be utilized apart from the float glass manufacturing process or well after formation and cutting of the glass ribbon.

In certain embodiments, the method provides is a dynamic deposition process. In these embodiments, the glass substrate is moving at the time of depositing the coating. Preferably, the glass substrate moves at a predetermined rate of, for example, greater than 1.27 m/min (50 in/min) as the coating is being formed thereon. In an embodiment, the glass substrate is moving at a rate of between 3.175 m/min (125 in/min) and 12.7 m/min (600 in/min) as the coating is being formed.

In certain embodiments, the glass substrate is heated. In an embodiment, the temperature of the glass substrate is about 1100° F. (593° C.) or more when the coating is deposited thereover or thereon. In another embodiment, the temperature of the glass substrate is between about 1100° F. (593° C.) and 1400° F. (760° C.).

The coating may be deposited by chemical vapor deposition (CVD). Preferably, the coating is deposited on the deposition surface of the glass substrate while the surface is at essentially atmospheric pressure. In this embodiment, the coating may be deposited by way of an atmospheric pressure CVD (APCVD) process. However, the method is not limited to forming the coating under atmospheric pressure conditions as, in other embodiments, the coating may be formed under low-pressure conditions.

In certain embodiments, the coating comprises aluminum, boron, and oxygen. Thus, in some embodiments, the method may comprise providing a source of an aluminum-containing compound and a source of a boron-containing compound. In some embodiments, the method may also comprise providing the source of the boron-containing compound and a source of oxygen. In other embodiments, the method may also comprise providing a source of one or more inert gases. Preferably, these sources are provided at a location outside the float bath chamber. Separate supply lines may extend from the sources of reactant (precursor) compounds and the one or more inert gases. As used herein, the phrases “reactant compound” and “precursor compound” may be used interchangeably to refer any or all of the aluminum-containing compound and the boron-containing compound, and/or used to describe the various embodiments thereof disclosed herein.

The method comprises forming a gaseous mixture. Precursor compounds suitable for use in the gaseous mixture may at some point be a liquid or a solid but are volatile such that they can be vaporized for use in the gaseous mixture. In certain embodiments, the gaseous mixture includes precursor compounds suitable for forming the coating at essentially atmospheric pressure. Once in a gaseous state, the precursor compounds can be included in a gaseous stream and utilized to form the coating.

For any particular combination of gaseous precursor compounds, the optimum concentrations and flow rates for achieving a particular deposition rate and coating thickness may vary. However, in order to form the coating as is provided by the method described herein, the gaseous mixture comprises an aluminum-containing compound and a boron-containing compound.

In certain embodiments, the aluminum-containing compound is an inorganic aluminum-containing compound. Preferably, in these embodiments, the aluminum-containing compound is an inorganic aluminum halide compound. An example of an inorganic aluminum halide compound suitable for use in the forming the gaseous mixture is aluminum chloride (AlCl₃). Aluminum chloride is preferred because it does not include carbon, which can become trapped in the coating during formation of the coating. However, the invention is not limited to aluminum chloride, as other halogenated aluminum-containing compounds may be suitable for use in practicing the method. In other embodiments, the aluminum-containing compound may be an organic aluminum-containing compound, preferably aluminum tri-isopropoxide.

In certain embodiments, the boron-containing compound is an organic boron-containing compound. Examples of organic boron-containing compounds suitable for use in the forming the gaseous mixture are tri-alkyl borates, such as trimethyl borate and triethyl borate (TEES), with triethyl borate being preferred. However, in certain embodiments, the invention may not limited to triethyl borate as other organic boron-containing compounds may be suitable for use in practicing the method. In other embodiments, the boron-containing compound may be an inorganic boron-containing compound.

In the embodiments where the boron-containing compound is an organic boron-containing compound, the boron-containing compound may also be an oxygen-containing compound. It has been discovered that with the addition of an organic boron-containing compound that includes oxygen to the gaseous mixture, the coating can be deposited directly on the glass substrate or over a previously depositing coating at a commercially acceptable deposition rate. Thus, in these embodiments, the gaseous mixture may consist essentially of the aluminum-containing compound and the boron-containing compound to form the coating over the glass substrate. In other embodiments, the gaseous mixture may include the aluminum-containing compound, the boron-containing compound, and an oxygen-containing compound or molecular oxygen (O₂). In an embodiment, the oxygen-containing compound may be an oxygen-containing organic compound such as, for example, a carbonyl compound. Preferably, the carbonyl compound is an ester. More preferably, the carbonyl compound is an ester having an alkyl group with a β hydrogen. Alkyl groups with a β hydrogen containing two to ten carbon atoms are preferred. Preferably, the ester is ethyl acetate (EtoAc). However, in other embodiments, the ester is one of ethyl formate, ethyl propionate, isopropyl formate, isopropyl acetate, n-butyl acetate or t-butyl acetate. In other embodiments, the oxygen-containing compound may be an oxygen-containing inorganic compound. In one such embodiment, the oxygen-containing compound is water (H₂O), which may be provided as steam.

In certain embodiments, the aluminum-containing compound is aluminum chloride and the boron-containing compound is triethyl borate. Thus, in these embodiments, the gaseous mixture may comprise aluminum chloride and triethyl borate. In other embodiments, the gaseous mixture may consist essentially of aluminum chloride and triethyl borate. In still other embodiments, the gaseous mixture may comprise aluminum chloride, triethyl borate, and molecular oxygen. In these embodiments, it may be preferred to practice the method by providing the boron-containing compound to the aluminum-containing compound in a predetermined ratio. For example, in an embodiment, the ratio of triethyl borate to aluminum chloride in the gaseous mixture is from 1:1 to 10:1. Preferably, the ratio of triethyl borate to aluminum chloride in the gaseous mixture is from 1:1 to 5:1. More preferably, the ratio of triethyl borate to aluminum chloride in the gaseous mixture is about 1:1 to 4:1.

Preferably, the precursor compounds are mixed to form the gaseous mixture. In an embodiment, the aluminum-containing compound is mixed with the boron-containing compound to form the gaseous mixture. In another embodiment, the aluminum-containing compound is mixed with the boron-containing compound and an oxygen-containing compound or molecular oxygen to form the gaseous mixture. In yet another embodiment, the aluminum-containing compound is mixed with the boron-containing compound and one or more inert gases utilized as carrier or diluent gas. Suitable inert gases include nitrogen (N₂), helium (He) and mixtures thereof.

Preferably, the gaseous mixture is delivered to a coating apparatus. In certain embodiments, the gaseous mixture is fed through a coating apparatus prior to forming the coating and discharged from the coating apparatus utilizing one or more gas distributor beams. Coating apparatuses known in the art are suitable for being utilized in the method.

Preferably, the gaseous mixture is formed prior to being fed through the coating apparatus. For example, the precursor compounds may be mixed in a feed line connected to an inlet of the coating apparatus. In other embodiments, the gaseous mixture may be formed within the coating apparatus. The gaseous mixture is directed toward and along the glass substrate. Utilizing a coating apparatus aids in directing the gaseous mixture toward and along the glass substrate. Preferably, the gaseous mixture is directed toward and along the glass substrate in a laminar flow.

Preferably, the coating apparatus extends transversely across the glass substrate and is provided at a predetermined distance thereabove. The coating apparatus is preferably located at a predetermined location. When the method is utilized in conjunction with the float glass manufacturing process, the coating apparatus is preferably provided within the float bath section thereof. However, the coating apparatus may be provided in the annealing lehr or in the gap between the float bath and the annealing lehr.

The gaseous mixture reacts at or near the deposition surface of the glass substrate to form the coating thereover. The method results in the deposition of a high quality coating directly on the glass substrate or a previously deposited coating. In particular, the coating formed using the method exhibits excellent coating thickness uniformity. When the coating is formed directly on the glass substrate, there are no intervening coatings between the coating and the glass substrate.

In an embodiment, the coating is a pyrolytic coating. In another embodiment, the coating comprises primarily aluminum, boron, and oxygen. In some embodiments, the atomic percentage of aluminum in the coating is less than 50%. In these embodiments, it may be preferred that the atomic percentage of aluminum in the coating is greater than 5.0%. In other embodiments, the atomic percentage of boron in the coating is less than 50%. In these embodiments, it may be preferred that the atomic percentage of boron in the coating is greater than 5.0%. In still other embodiments, the combined atomic percentage of aluminum and boron in the coating is less than 50%. In these embodiments, it may be preferred that the combined atomic percentage of aluminum and boron in the coating is greater than 5.0%. In still other embodiments, the combined atomic percentage of aluminum and boron in the coating may be greater than 25%. In these embodiments, the combined atomic percentage of aluminum and boron in the coating may be 25-50%. However, in some embodiments, the coating may contain contaminants of, for example, carbon and/or chlorine. Preferably, when the coating contains contaminants, the contaminants are provided in trace amounts or less. As used herein, the phrase “trace amount(s)” is an amount of a constituent of a coating layer that makes up less than 0.01 wt. % of the coating layer.

Preferably, the coating exhibits a medium refractive index. For example, the coating may exhibit a refractive index of 1.8 or less. More preferably, the coating has a refractive index of between 1.5 and 1.8. It should be noted that the refractive index values described herein are reported as an average value across 400-780 nm of the electromagnetic spectrum. Forming the coating so that it exhibits a medium refractive index permits desired optical effects to be achieved when the coating is used in, for example, combination with other coatings or a particular application like an architectural glazing.

A feature of the method is that it allows for the formation of the coating at commercially viable deposition rates. For example, utilizing the method, the coating may be formed at a dynamic deposition rate of 13 nm per second (nm/sec.) or more, preferably 16 nm/sec. or more. Additionally, an advantage of the method is that it is more efficient than known processes for forming coatings that comprise aluminum and oxygen. Thus, commercially viable deposition rates can be achieved using less precursor materials than in the known processes which reduces the cost to form such coatings. For example, when the boron-containing compound includes oxygen, the coating can be formed over the glass substrate without the need for an additional oxygen-containing compound or molecular oxygen.

As noted above, the coating may be formed over one or more previously deposited coatings. For example, a silica (SiO₂) coating or a tin oxide (SnO₂) coating may be deposited over the glass substrate prior to forming the coating thereon. Advantageously, when the coating is deposited on a previously deposited coating, the roughness exhibited by the resulting coated glass article may be reduced. For example, when the coating is deposited on a previously deposited tin oxide coating, the resulting coated glass article may exhibit a reduced roughness compared with a glass coated with SnO₂ alone.

The previously deposited coating(s) may be formed in conjunction with the float glass manufacturing process or as part of another manufacturing process and may be formed by pyrolysis or by another coating deposition process, and/or by utilizing one or more additional coating apparatuses. Additionally, the method described herein may be utilized in combination with one or more additional coatings formed over the coating to achieve a desired coating stack. The additional coating(s) may be formed in conjunction with the float glass manufacturing process shortly after forming the coating or as part of another manufacturing process. Also, these additional coating(s) may be formed by pyrolysis or by another coating deposition process, and/or by utilizing one or more additional coating apparatuses.

As discussed, above, the method may be carried out in conjunction with the manufacture of the glass substrate in the well-known float glass manufacturing process. The float glass manufacturing process is typically carried out utilizing a float glass installation such as the installation 10 depicted in the FIG. 1. However, it should be understood that the float glass installation 10 described herein is only illustrative of such installations.

As illustrated in the FIG. 1, the float glass installation 10 may comprise a canal section 20 along which molten glass 19 is delivered from a melting furnace, to a float bath section 11 wherein the glass substrate is formed. In this embodiment, the glass substrate will be referred to as a glass ribbon 8. The glass ribbon 8 is a preferable substrate on which the coating is deposited. However, it should be appreciated that the glass substrate is not limited to being a glass ribbon.

The glass ribbon 8 advances from the bath section 11 through an adjacent annealing lehr 12 and a cooling section 13. The float bath section 11 includes: a bottom section 14 within which a bath of molten tin 15 is contained, a roof 16, opposite side walls (not depicted) and end walls 17. The roof 16, side walls and end walls 17 together define an enclosure 18 in which a non-oxidizing atmosphere is maintained to prevent oxidation of the molten tin 15.

In operation, the molten glass 19 flows along the canal 20 beneath a regulating tweel 21 and downwardly onto the surface of the tin bath 15 in controlled amounts. On the molten tin surface, the molten glass 19 spreads laterally under the influence of gravity and surface tension, as well as certain mechanical influences, and it is advanced across the tin bath 15 to form the glass ribbon 8. The glass ribbon 8 is removed from the bath section 11 over lift out rolls 22 and is thereafter conveyed through the annealing lehr 12 and the cooling section 13 on aligned rolls. The deposition of the coating preferably takes place in the float bath section 11, although it may be possible for deposition to take place further along the glass production line, for example, in the gap 28 between the float bath 11 and the annealing lehr 12, or in the annealing lehr 12.

As illustrated in the FIG. 1, the coating apparatus 9 is shown within the float bath section 11. However, the coating formed by the method may be deposited by forming a plurality of coatings consecutively. Thus, depending on the thickness of the coating desired, the coating may be formed utilizing one coating apparatus 9 or a plurality of coating apparatuses.

A suitable non-oxidizing atmosphere, generally nitrogen or a mixture of nitrogen and hydrogen in which nitrogen predominates, is maintained in the float bath section 11 to prevent oxidation of the molten tin 15 comprising the float bath. The glass ribbon is surrounded by float bath atmosphere. The atmosphere gas is admitted through conduits 23 operably coupled to a distribution manifold 24. The non-oxidizing gas is introduced at a rate sufficient to compensate for normal losses and maintain a slight positive pressure, on the order of between about 0.001 and about 0.01 atmosphere above ambient atmospheric pressure, so as to prevent infiltration of outside atmosphere. For purposes of the describing the invention, the above-noted pressure range is considered to constitute normal atmospheric pressure.

The coating is preferably formed at essentially atmospheric pressure. Thus, the pressure of the float bath section 11, annealing lehr 12, and/or in the gap 28 between the float bath 11 and the annealing lehr 12 may be essentially atmospheric pressure.

Heat for maintaining the desired temperature regime in the float bath section 11 and the enclosure 18 is provided by radiant heaters 25 within the enclosure 18. The atmosphere within the lehr 12 is typically atmospheric air, as the cooling section 13 is not enclosed and the glass ribbon 8 is therefore open to the ambient atmosphere. The glass ribbon 8 is subsequently allowed to cool to ambient temperature. To cool the glass ribbon 8, ambient air may be directed against the glass ribbon 8 as by fans 26 in the cooling section 13. Heaters (not depicted) may also be provided within the annealing lehr 12 for causing the temperature of the glass ribbon 8 to be gradually reduced in accordance with a predetermined regime as it is conveyed therethrough.

### Examples

The following examples are presented solely for the purpose of further illustrating and disclosing certain embodiments of the method.

Examples of the method are described below and illustrated in TABLE 1. In TABLE 1, the examples within the scope of the invention are Ex 1-Ex 6.

A soda-lime-silica glass substrate was utilized in examples Ex 1-Ex 6. The glass substrate utilized in each of Ex 1-Ex 6 was moving when the coating was formed. The deposition surface of the glass substrate was at essentially atmospheric pressure when the coating was formed.

For Ex 1, a tin oxide coating was deposited on the glass substrate prior to depositing the coating thereover. Thus, the resulting coated glass article of Ex 1 is of a glass/tin oxide/coating arrangement. For Ex 2-Ex 6, an undercoating was not deposited. Thus, each coating was deposited directly on the glass substrate.

A gaseous mixture comprising certain precursor compounds was formed for each of Ex 1-Ex 6. The amounts of the individual gaseous precursor compounds are as listed in TABLE 1. The gaseous mixtures utilized for Ex 1-Ex 6 also comprised inert gas(es) which made up the balance of the gaseous mixtures. The line speed for Ex 1-Ex 6, i.e. the speed of the glass substrate moving beneath the coating apparatus from which the gaseous precursor compounds were delivered, was 1.90 m/min.

The coating thicknesses reported in TABLE 1 are reported in nanometers, and are derived from scanning electron microscope images of each coating. Also, the atomic percentage of aluminum and boron in each coating is reported in TABLE 1. The atomic percentage of aluminum and boron in each coating was measured by X-ray photoelectron spectroscopy (XPS).

TABLE 1

| | | | | | | | | Deposition |
|---|---|---|---|---|---|---|---|---|
| | Nucleation | | | | Thickness | | | Rate |
| Examples | layer | % AlCl₃ | % O₂ | % TEB | (nm) | Aluminum | Boron | (nm/sec.) |
| Ex 1 | SnO₂ | 0.8 | 0.0 | 3.2 | 220 | 20.4 | 26.5 | 17.7 |
| Ex 2 | none | 0.8 | 0.0 | 3.2 | 200 | 20.8 | 25.0 | 16.1 |
| Ex 3 | none | 0.8 | 0.0 | 3.2 | 230 | 22.0 | 22.0 | 18.5 |
| Ex 4 | none | 0.8 | 5.0 | 3.2 | 170 | 20.2 | 23.8 | 13.7 |
| Ex 5 | none | 0.8 | 10.0 | 3.2 | 165 | 20.2 | 24.1 | 13.3 |
| Ex 6 | none | 0.8 | 2.0 | 3.2 | 190 | 20.1 | 23.4 | 15.3 |

As shown in TABLE 1, the method allows for a coating with a thickness of greater than 100 nm to be deposited over a moving glass substrate. Also, the coatings of Ex 1-Ex 6 each comprised aluminum, boron, and oxygen. As illustrated, the atomic percentage of aluminum in each coating was between 5% and 50%, the atomic percentage of boron in each coating was between 5% and 50%, and the combined atomic percentage of aluminum and boron in the coating was between 25% and 50%.

The foregoing description is considered as illustrative only of the principles of the invention. Further, since numerous modifications and changes will readily occur to those skilled in the art, it is not desired to limit the invention to the exact construction and processes shown and described herein. Accordingly, all suitable modifications and equivalents may be considered as falling within the scope of the invention as defined by the claim which follows.

1.-30. (canceled)

31. A method of making a coated glass article comprising:
providing a glass substrate;
forming a gaseous mixture comprising an aluminum-containing compound, a boron-containing compound, and an inert gas;
delivering the gaseous mixture to a location above a major surface of the glass substrate to deposit a coating comprising aluminum, boron, and oxygen over the major surface of the glass substrate.

32. The method of claim 31, wherein the coating is deposited on the deposition surface of the glass substrate while the surface is at essentially atmospheric pressure.

33. The method of claim 31, wherein the temperature of the glass substrate is 1100° F. or more when the coating is deposited.

34. The method of claim 31, wherein the temperature of the glass substrate is between 1100° F. and 1400° F. when the coating is deposited.

35. The method of claim 31, wherein the aluminum-containing compound is an inorganic aluminum-containing compound.

36. The method of claim 31, wherein the aluminum-containing compound is an inorganic aluminum halide compound.

37. The method of claim 31, wherein the aluminum-containing compound is aluminum chloride.

38. The method of claim 31, wherein the boron-containing compound is an organic boron-containing compound.

39. The method of claim 31, wherein the boron-containing compound is a tri-alkyl borate, preferably wherein the boron-containing compound is triethyl borate.

40. The method of claim 31, wherein the gaseous mixture further comprises an oxygen-containing compound or molecular oxygen.

41. The method of claim 31, wherein the gaseous mixture further comprises water.

42. The method of claim 31, wherein the gaseous mixture further comprises an ester, preferably an ester having an alkyl group with a β hydrogen, more preferably ethyl acetate.

43. The method of claim 31, wherein the boron-containing compound is an organic boron-containing and oxygen-containing compound, and the gaseous mixture consists essentially of the aluminum-containing compound and the boron-containing compound.

44. The method of claim 31, wherein the gaseous mixture further comprises aluminum chloride, triethyl borate, and molecular oxygen, and wherein the ratio of triethyl borate to aluminum chloride in the gaseous mixture is from 1:1 to 10:1, preferably wherein the ratio of triethyl borate to aluminum chloride in the gaseous mixture is from 1:1 to 5:1, more preferably wherein the ratio of triethyl borate to aluminum chloride in the gaseous mixture is from 1:1 to 4:1.

45. The method of claim 31, wherein the coating exhibits a refractive index of 1.8 or less, preferably wherein the coating exhibits a refractive index of between 1.5 and 1.8.

46. The method of claim 31, wherein the coating is formed at a dynamic deposition rate of 13 nm/sec. or more, preferably wherein the coating is formed at a dynamic deposition rate of 16 nm/sec. or more.

47. The method of claim 31, wherein the glass substrate has a low iron content, preferably wherein the glass substrate comprises 0.20 weight % Fe₂O₃ (total iron) or less, more preferably wherein the glass substrate comprises 0.1 weight % Fe₂O₃ (total iron) or less, most preferably wherein the glass substrate comprises 0.02 weight % Fe₂O₃ (total iron) or less.

48. The method of claim 31, wherein the coating is deposited over a silica layer.

49. The method of claim 31, wherein the coating is deposited over a tin oxide layer.

50. The method of claim 31, wherein the coating is deposited directly on a surface of the glass substrate.
